(19) United States
(12) Patent Application Publication
(10) Pub. No.: US 2002/0163677 A1
(43) Pub. Date: Nov. 7, 2002

(54) Method for determining a local compensation for pixel brightness

(76) Inventor: Kuo-Jeng Wang, Kaohsiung (TW)

Correspondence Address: J.C. Patents, Inc., 1340 Reynolds Ave., Suite 114, Irvine, CA, 92614, US

(21) Appl. No.: 09/849,461

(22) Filed: May 4, 2001

(51) Int. Cl. B41J 1/00; G06F 15/00; G03F 3/08

(52) U.S. Cl. 358/520; 358/1.9

(57) ABSTRACT

A method for determining a local compensation for the pixel brightness is applied to evaluate the pixels of a scanned document for which brightness needs to be compensated. The method comprises, for each pixel, first evaluating the difference between the corresponding brightness value and darkness value. The result of the difference then is compared to a predetermined level value. If the difference is less than the predetermined level value, the brightness of the corresponding pixel is compensated for.

### BACKGROUND OF THE INVENTION

1. Field of the Invention

The present invention relates to image processing. More particularly, the present invention relates to a method for determining a compensation for pixel brightness generated when scanning a document.

2. Description of the Related Art

FIG. 1 is a schematic view partially illustrating a conventional scanning of a picture. A slidable light source pad 11 carries a lamp tube 13 that moves along a document 12 being scanned. The lamp tube 13 emits a light onto the document 12, an image signal from the picture 12 is reflected via a plurality of reflective mirrors 153, 155 and 151, and the image signal is finally input to a charge coupled device (CCD) 17.

FIG. 2 is a graph schematically showing light distribution along a conventional lamp tube. Ideally, the light should be uniformly emitted along the lamp tube 13. However, because the conventional lamp tube 13 is long, the light emitted at either extremity thereof is relatively less intense. As a result, a compensation for pixel brightness generated by the scanning of the lamp tube 13 along the document 12 has to be applied to all the pixels of the scanned document in a conventional document scan. Such an operation disadvantageously slows down scanning speed.

### SUMMARY OF THE INVENTION

One major aspect of the present invention therefore is to provide a method for determining to which pixels of a scanned document a brightness compensation is to be applied. In the present invention, the lack of brightness of the pixels thus is locally compensated, in contrast to a conventional brightness compensation that is applied to all the pixels of the scanned document.

To attain the foregoing and other objectives, the present invention provides a method that determines a local compensation for the pixel brightness. First, for each pixel of a scanned document, the difference between the brightness value and the darkness value is evaluated. The difference between the brightness value and the darkness value of each pixel then is compared to a predetermined value. Finally, if the difference is less than the predetermined value, compensation is made for the brightness of the corresponding pixel.

By achieving the above method, the contrast between brightness and darkness of each pixel is emphasized and the scanning speed increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic view partially illustrating a conventional scanning;

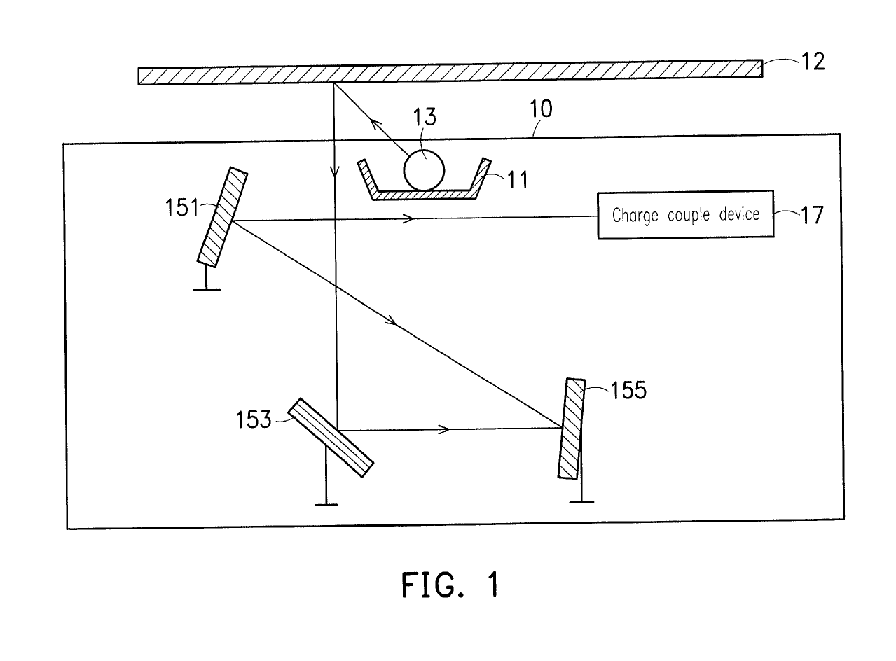

FIG. 2 is a graph schematically illustrating a drawback related to the conventional scanning;

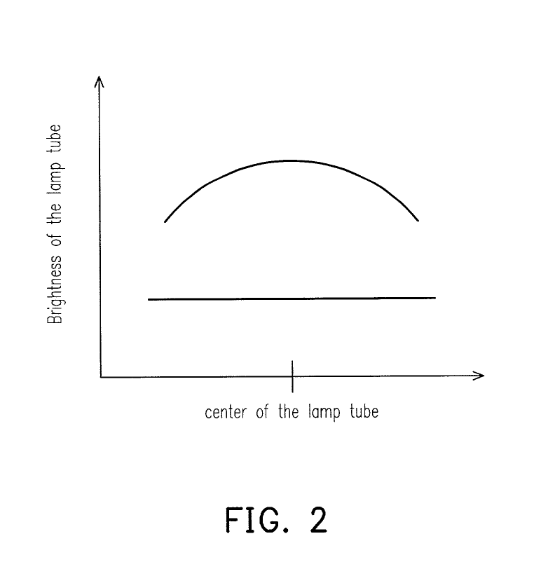

FIG. 3 is a flow chart schematically illustrating a method for determining a local compensation for the pixel brightness of a scanned document according to preferred embodiment of the present invention;

FIG. 4 is a flow chart schematically illustrating another example of the method for determining a local compensation for the pixel brightness according to the preferred embodiment of the present invention; and

FIG. 5 is a flow chart schematically illustrating another variation of the method for determining a local compensation for the pixel brightness of a scanned document according to the preferred embodiment of the present invention.

### DESCRIPTION OF THE PREFERRED EMBODIMENTS

The following detailed description of the embodiments and examples of the present invention with reference to the accompanying drawings is only illustrative and not limiting.

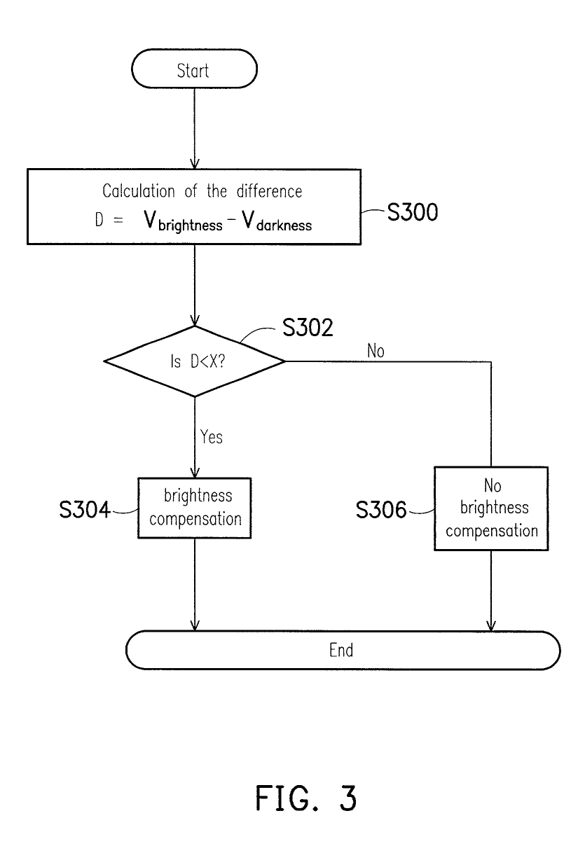

FIG. 3 is a flow chart schematically illustrating a method for determining a local compensation for the pixel brightness according to a preferred embodiment of the present invention. Within a scanner, a lamp tube, after having projected its light on a reference area, scans a document and generates a plurality of pixels of the scanned document, the pixels having nonuniform brightness values and corresponding darkness values.

First, in step s300, each brightness value and corresponding darkness value are submitted to a calculation that evaluates the difference between the brightness value and the darkness value of each pixel according to the equation D=V_{brightness}−V_{darkness}. In step s302, the difference thus obtained for each pixel is compared to a predetermined level value X.

If the difference D of one of the pixels is less than the predetermined level value X, a brightness compensation is applied to the corresponding pixel (step s304). If the difference D of one of the pixels is greater than or equal to the predetermined level value X, no brightness compensation is made(step s306).

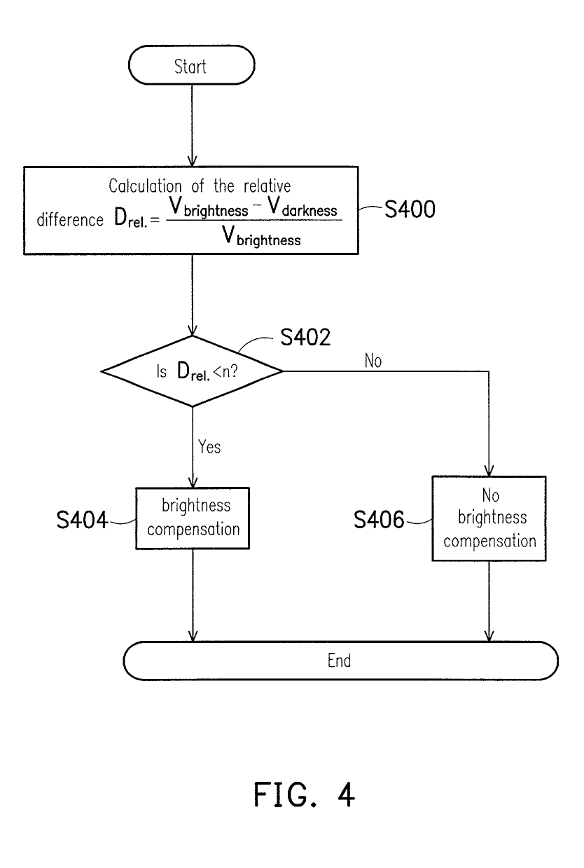

Referring to FIG. 4, a flow chart schematically illustrates another example of the method of the present invention. In step s400, each brightness value and corresponding darkness value are submitted to a calculation that evaluates the relative difference between the brightness value and the darkness value of each pixel according to the equation Dᵣₑₗ=(V_{brightness}−V_{darkness})/V_{brightness}. In step s402, the relative difference thus obtained for each pixel is compared to a predetermined level value n.

If the relative difference Dᵣₑₗ of one of the pixels is less than the predetermined level value n, a brightness compensation then is applied to the corresponding pixel (step s404). If the relative difference Dᵣₑₗ of one of the pixels is greater than or equal to the predetermined level value n, no brightness compensation is made (step s406).

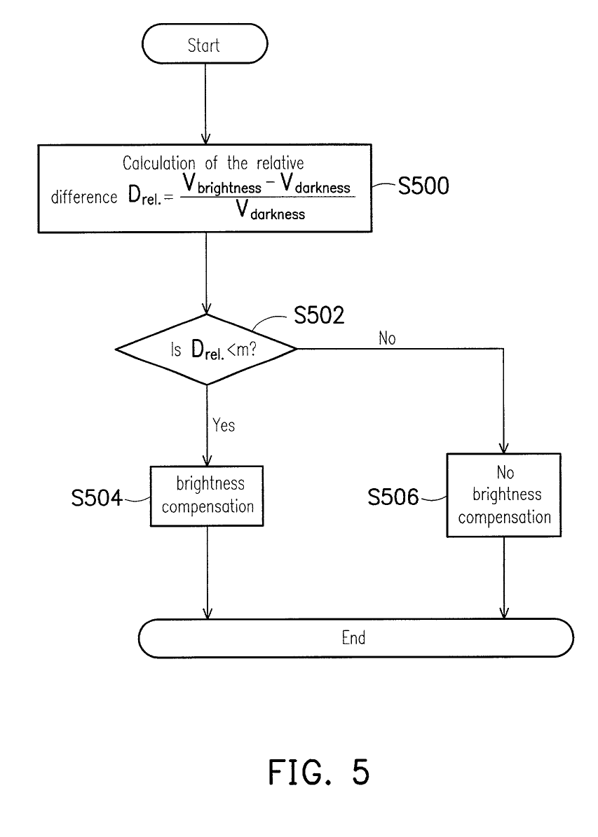

FIG. 5 is a flow chart schematically illustrating a method according to another possible example of the present invention. In step s500, each brightness value and its corresponding darkness value are submitted to a calculation that evaluates the relative difference between the brightness value and the darkness value of each pixel according to the equation Dᵣₑₗ=(V_{brightness}−V_{darkness})/V_{darkness}. Then, in step s502, the relative difference thus obtained for each pixel is compared to a predetermined level value m.

If the relative difference Dᵣₑₗ of one of the pixels is less than the predetermined level value m, a brightness compensation is applied to the corresponding pixel (step s504). If the relative difference Dᵣₑₗ of one of the pixels is greater than or equal to the predetermined level value n, no brightness compensation is made (step s506).

With the above-described method, the brightness compensation thus is advantageously only applied to the pixels whose brightness needs be compensated for. As a result, the contrast between brightness and darkness is advantageously emphasized and the speed of the whole scanning advantageously increased.

It will be apparent to those skilled in the art that various modifications and variations can be made to the structure of the present invention without departing from the scope or spirit of the invention.

What is claimed is:

1. A method for determining a local compensation for the pixel brightness, applied to a plurality of pixels of a scanned document, the pixels having nonuniform brightness values and corresponding darkness values generated after light of a lamp tube has been projected onto a reference area and on the document, the method comprising:
for each pixel of the scanned region, evaluating a difference between a brightness value and a darkness value therefor;
comparing the difference between the brightness value and the darkness value of each pixel to a predetermined level value; and
applying a brightness compensation only to the pixels having a difference between the brightness value and darkness value less than the predetermined level value.

2. The method of claim 1, wherein the difference between the brightness value and the darkness value is evaluated via deducting the darkness value from the brightness value.

3. The method of claim 1, wherein the difference between the brightness value and the darkness value is evaluated via deducting the darkness value from the brightness value, and dividing the result by the brightness value.

4. The method of claim 1, wherein the difference between the brightness value and the darkness value is evaluated via deducting the darkness value from the brightness value, and dividing the result by the darkness value.
